(19) United States
(12) Patent Application Publication
(10) Pub. No.: US 2006/0249202 A1
(43) Pub. Date: Nov. 9, 2006

(54) Photovoltaic cell

(76) Inventors: Seunghyup Yoo, Duluth, GA (US); Benoit Domercq, Atlanta, GA (US); Bernard Kippelen, Decatur, GA (US)

Correspondence Address: NEEDLE & ROSENBERG, P.C., SUITE 1000, 999 PEACHTREE STREET, ATLANTA, GA, 30309-3915, US

(21) Appl. No.: 11/232,188

(22) Filed: Sep. 20, 2005

Related U.S. Application Data
(60) Provisional application No. 60/611,467, filed on Sep. 20, 2004.

(51) Int. Cl. H01L 31/00

(52) U.S. Cl. 136/263

(57) ABSTRACT

The novel light conversion system includes photosensitive optoelectronic devices, or photovoltaic cells, that convert electromagnetic radiation into electrical currents without applying an external voltage. Power conversion efficiency is a primary criterion for evaluating the performance of photovoltaic cells. Photovoltaic cells with high power-conversion efficiencies are more cost effective and more suitable replacements for conventional energy sources. This novel light conversion system uses a polycrystalline organic material with unique material properties for achieving high, power-conversion efficiencies.

### CROSS REFERENCE TO RELATED APPLICATIONS

This application claims priority to U.S. Provisional Patent Application with application No. 60/611,467 entitled “Organic Polycrystalline Photovoltaic Cells and Image Sensors Using Pentacene and Methods Thereof”, filed on Sep. 20, 2004. This application in its entirety is hereby incorporated by reference.

### STATEMENT REGARDING FEDERALLY SPONSORED RESEARCH

This material is based upon work supported in part by the STC Program of the National Science Foundation under Agreement Number DMR-0120967, by the Office of Naval Research (Contract Number N00014-04-1-0120), by the National Renewable Energy Laboratory, and by an NSF CAREER program. The government has certain rights in this invention.

### DESCRIPTION OF THE STATE OF THE ART

Continuous population growth and economic development increases demand for reliable energy sources. The limited quantity of fossil fuels, which currently dominate energy markets, cannot meet this increase in demand. In addition to the limited quantity of these fuels, they often emit gases that are harmful to the environment. Consequently, there has been a push toward developing alternative energy sources.

Photovoltaic energy generation is a promising alterative energy source because it directly converts energy from sun light into electricity. Therefore, this type of energy generation is an unlimited resource and is environmentally friendly. For photovoltaic energy to be a viable alternative, the cost must be comparable to the cost of electricity. Consequently, an affordable photovoltaic solution necessitates a low cost, which corresponds to an efficiency larger than five to ten percents and a lifetime longer than 15 years. There remains an unmet need in the art.

### BRIEF DESCRIPTION OF THE DRAWINGS

The invention can be better understood with reference to the following figures. The components within the figures are not necessarily to scale, emphasis instead being placed upon clearly illustrating the organic light conversion system. Moreover, in the figures, like reference numerals designate corresponding parts or blocks throughout the different views.

FIG. 1 is a block diagram illustrating an organic light conversion system.

FIG. 2A is a cross-sectional view of the photovoltaic cell of FIG. 1 illustrating the general structure of this photovoltaic cell.

FIG. 2B is a cross-sectional view of an alternative material structure for the photovoltaic cell of FIG. 2A.

FIG. 3A-3G are alternative molecular structures for the carrier transport layer of FIG. 2A.

FIG. 4A is a circuit diagram illustrating an equivalent electrical circuit for the photovoltaic cell of FIG. 1.

FIG. 4B is a graph of the current-voltage relationship for the electrical circuit diagram of FIG. 4A.

FIG. 5A-5E are energy level block diagrams illustrating how the organic photovoltaic cell is operating under illumination.

FIG. 6A illustrates the effect of exciton diffusion length on steady-state exciton distributions in the photovoltaic cell assuming a single pass absorption of the light.

FIG. 6B illustrates the effect of exciton diffusion length on steady-state exciton distributions in the photovoltaic cell assuming a double pass where the light is reflected by the back electrode.

FIG. 7A illustrates the interplay between absorption coefficient, the layer thickness and the exciton diffusion length and its effect on the external quantum efficiency assuming a single pass absorption of the light.

FIG. 7B illustrates the interplay between absorption coefficient, the layer thickness and the exciton diffusion length and its effect on the external quantum efficiency assuming a double pass where the light is reflected by the back electrode.

FIG. 8A is a cross-sectional view of an illustrative photovoltaic cell under illumination.

FIG. 8B is a cross-sectional view of an alternative material structure for the photovoltaic cell of FIG. 8A.

FIG. 9A is the experimental and calculated external quantum efficiency as a function of the incident wavelength for the photovoltaic cell illustrated in FIG. 8B.

FIG. 9B is the experimental electrical characteristic of the photovoltaic cell illustrated in FIG. 8B

FIG. 10A is the X-ray diffraction pattern from a pentacene thin film deposited on ITO (top) and from a blank ITO substrate (bottom).

FIG. 10B illustrates the analysis of the X-ray diffraction pattern to estimate the mean dimension of the crystallite in a pentacene film.

FIG. 11 illustrates the structure of polycrystalline pentacene layer of FIG. 8 measured by atomic force microscopy.

While the invention is susceptible to various modifications and alternative forms, specific embodiments have been shown by way of example in the drawings and subsequently are described in detail. It should be understood, however, that the description herein of specific embodiments is not intended to limit the invention to the particular forms disclosed. In contrast, the intention is to cover all modifications, equivalents, and alternatives falling within the spirit and scope of the invention as defined by the appended claims.

### DETAILED DESCRIPTION OF EMBODIMENTS

As used in the specification and the appended claims, the singular forms “a,” “an” and “the” include plural referents unless the context clearly dictates otherwise. Similarly, “optional” or “optionally” means that the subsequently described event or circumstance may or may not occur, and that the description includes instances where the event or circumstance occurs and instances where it does not.

The novel light conversion system includes photosensitive optoelectronic devices, or photovoltaic cells, that convert electromagnetic radiation into electrical currents without applying an external voltage. Power conversion efficiency is a primary criterion for evaluating the performance of photovoltaic cells. Photovoltaic cells with high power-conversion efficiencies are more cost effective and more suitable replacements for conventional energy sources. This novel light conversion system uses a polycrystalline organic material with unique material properties for achieving high, power-conversion efficiencies.

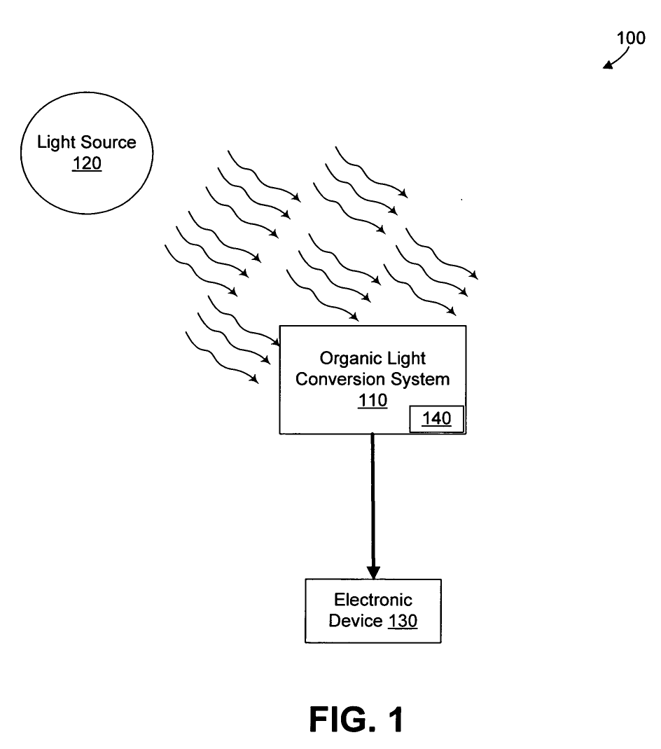

Turning now to FIG. 1, this figure is a block diagram illustrating an environment 100 for using an organic light conversion system 110. Within the environment 100, numerous light sources such as light source 120 can supply light to the light conversion system 110. These light sources can include the sun, artificial incoherent light sources such as phosphorescent and fluorescent bulbs, solid state light-emitting diodes, and coherent light sources such as lasers. The light conversion system 110 converts a large percentage of the incident light from the light source 120 to electrical energy. The conversion system 110 can supply this electrical energy to a receiver device, such as an electronic device 130. Consequently, the organic light conversion system can power components within this electronic device or recharge batteries that are used to power this electronic device. The light conversion system 110 can be formed from individual photovoltaic cells. For example, the light conversion system 110 can be formed from a single photovoltaic cell 140, or a plurality of photovoltaic cells arranged in arrays. Within such arrays, the cells can be connected in series, in parallel or in a combination of both in order to fulfill specific voltage and current objectives for a given application.

Material Composition of the Photovoltaic Cell

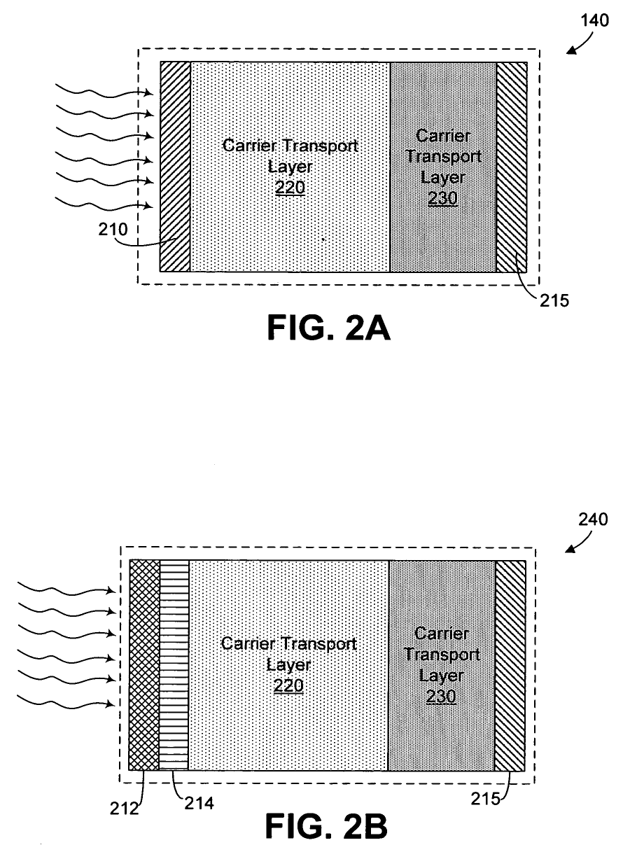

Turning now to FIG. 2A, this figure is a cross sectional view of photovoltaic cell 140 illustrating the general structure of this cell. The photovoltaic cell 140 includes an electrode depicted as layer 210, an electrode depicted as layer 215, carrier transport layer 220, and carrier transport layer 230. At least one of the electrodes layers 210 and 215 can be optically transparent or semi-transparent so that light can be transmitted and absorbed in the carrier transport layers 220 and 230. Carrier transport layers 220 and 230 can be good light absorbers. While the layer 210 can function as either a cathode or an anode for the photovoltaic cell 140, for simplicity this layer is subsequently referred to as the anode. While this section explores the material structure of the photovoltaic cell, the benefits gained from using this structure is discussed in subsequent sections.

The anode, or layer 210, can include transparent conductive oxides, transparent conductive polymers, inorganic oxides, or some other suitable chemical material. Examples of transparent conductive oxides (TCO) include, but are not limited to, indium tin oxide, fluorine-doped tin oxide (FTO), zinc oxide (ZO), aluminum- or indium-doped zinc oxide, tin oxide, magnesium-indium-oxide cadmium-tin-oxide, or some other suitable oxides. Suitable transparent conducting polymers (TCPs) include 3,4-polyethylenedioxythiophene:polystyrene sulfonate (PEDOT:PSS), polyaniline, polypyrrole doped with iodine or other Lewis acids, or some other suitable transparent conducting polymers.

In an alternative implementation, the anode, or layer 210, can include multiple layers. An additional layer can reduce current leakage between the anode and cathode. For example, the anode can have a lower TCO layer 212 and an upper TCP layer 214 positioned adjacent to the carrier transport layer 220 as shown in FIG. 2B. Another multilayer anode can be created by treating TCO layer 212 with a self-assembled monolayer (SAM) 214. Self-assembled monolayers are used to modify the physical and chemical properties of surfaces and can promote molecular ordering of photoactive organic layers, like the carrier transport layer 220.

The cathode, or layer 215, can include metals, metal alloys, or a metal and buffer layer combination that functions as the cathode. Examples of metals and metal alloys may include, but are not limited to, aluminum, gold, silver, magnesium, calcium, copper, metal mixtures, or the like. The buffer layer can be thin and can be prepared from lithium fluoride, lithium oxide, cesium fluoride, or other alkali metal and alkali earth metal containing materials. The buffer material can be a thin organic layer that prevents metal atoms from diffusing into carrier transport layer 230 during deposition of layer 215.

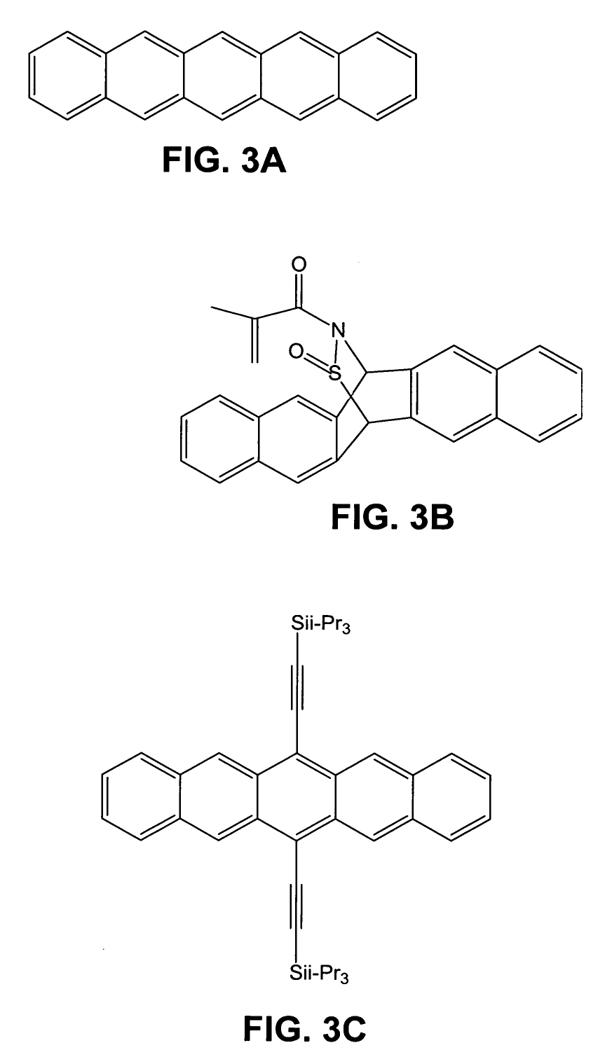

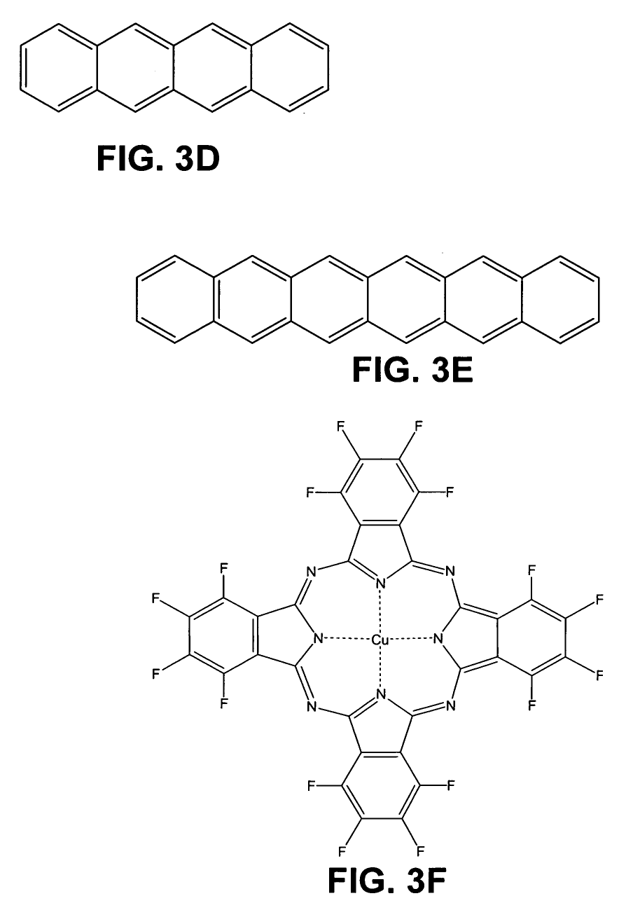

The photovoltaic cell 140 also includes carrier transport layer 220 and carrier transport layer 230. Either carrier transport layer can function as a hole-transport layer or an electron-transport layer, as desired. For the sake of simplicity, the carrier transport layer 220 is designated as the hole-transport layer and carrier transport layer 230 is designated as the electron transport layer. To form the carrier transport layer 220, physical vapor deposition in a vacuum, or some other suitable deposition method can be used. This hole transport layer can consist of an oligoacene, which is a molecule with a series of linear hydrocarbons containing N-fused aromatic rings (C_{4N+2}H_{2N+4}). Oligoacenes can include pentacene, which has 5 fused aromatic rings (see FIG. 3A), a strong absorption within the visible spectrum, high carrier mobility, and a large exciton diffusion length, which is described below. Alternatively, layers of pentacene or pentacene derivatives prepared from solutions using soluble precursors (see FIG. 3B for an example), can be used as the hole transport layer. Even still, functionalized pentacene (see FIG. 3C for an example), can be used. Other oligoacenes with absorption in the visible and near IR spectrum can also be used, such as tetracene (see FIG. 3D), hexacene (see FIG. 3E), and other suitable oligoacenes.

The carrier transport layer 230, or electron transporting layer, can be prepared from organic molecules with a large electron affinity. Electron affinity is the energy absorbed when an electron is added to an atom or molecule. Organic molecules, or carbon-based molecules, that can be used in the electron transporting layer can include fullerenes and their derivatives, perylene diimides, derivatives of perylene diimides, coronenes, derivatives of coronenes, and metallo hexadecafluorophthalocyanines, such as copper hexadecafluorophthalocyanines (F₁₆CuPc) as shown in FIG. 3G. Some fullerenes can include C₆₀ and C₇₀. In addition, compositions included in this layer can be selected such that they have an absorption spectrum that is complementary to the absorption spectrum of molecules that form the hole-transport layer 220. In this case, more light can be harvested from the light source, increasing the photocurrent that is produced and consequently increasing the efficiency of the device.

Electrical Characteristics for the Photovoltaic Cell

By carefully selecting materials for the photovoltaic cell 140, this cell can operate quite efficiently at a nominal cost. To describe the operation of the photovoltaic cell 140, the cell's electrical characteristics are considered. Subsequently, the physical principles resulting in the conversion from light energy to electrical energy are considered. More specifically, exciton diffusion length is defined and its role in producing the low-cost, efficient photovoltaic cell is also described.

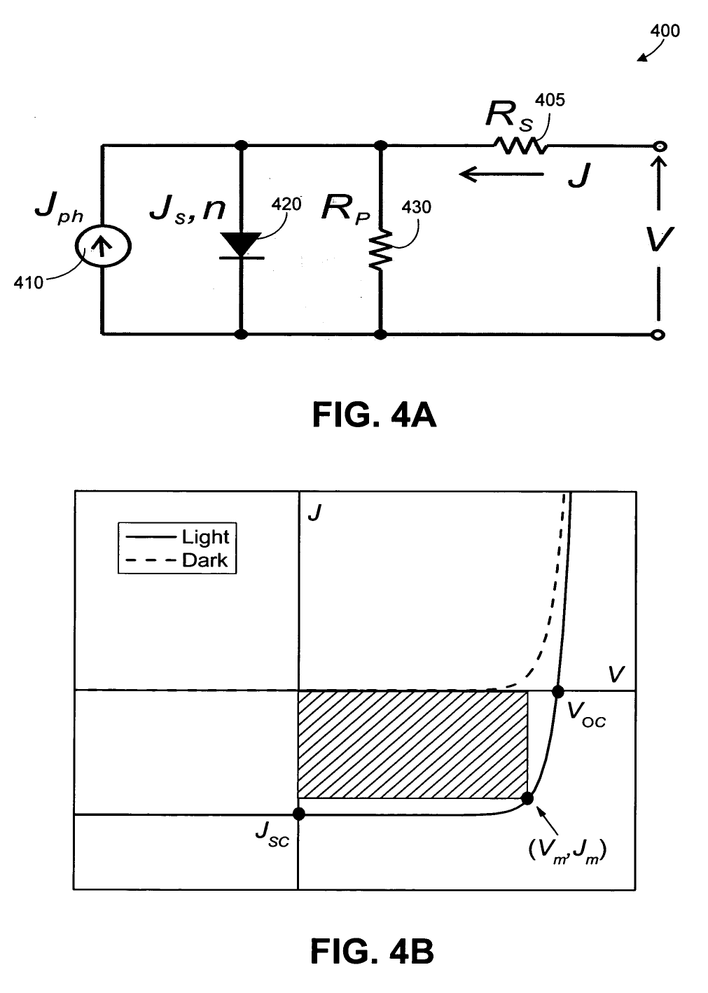

The photovoltaic cell 140 can have electrical characteristics that resemble a combination of a current source and a diode semiconductor device with a nonlinear current-voltage characteristic. Turning now to FIG. 4A, this figure is a circuit diagram 400 illustrating an equivalent circuit, or similarly operating circuit, for the photovoltaic cell 140. In this circuit, a diode 420 is connected to a current source 410 and a resistor 430 in parallel, and to a resistor 405 in series. The resistor 405 is a series resistor with a corresponding resistance R_{S}. In contrast, the resistor 430 is a shunt resistor with a corresponding resistance R_{P}.

The current source 410 is a DC current source with a current density that corresponds to the photocurrent density J_{pb}. The photocurrent density describes the current density produced by an ideal cell at zero voltage. The diode 420 is characterized by its reverse saturation current density J_{S}and ideality factor n. The ideality factor is a factor>1 that describes deviations from the current-voltage of an ideal diode. The resistance R_{P} takes into account loss of carriers via recombination and loss of carriers due to leakage paths that can be caused, for example, through pinholes, or discontinuities, in the carrier transport layers. On the other hand, the resistance R_{S} is attributed to the bulk resistance (i.e., the effective resistance of all layers within the photovoltaic cell 140), the resistance of the contacts between the transport layers and the adjacent electrodes (i.e., anode 210 and cathode 215). When cells are arranged in arrays, conducting lines used to connect them can add additional resistance.

The performance of a photovoltaic cell can be evaluated by its power conversion efficiency, which is defined by the ratio of the maximum electrical power that this cell can produce, divided by the optical power that is incident on the cell. The power conversion efficiency can be determined using the current-voltage relationship illustrated in FIG. 4B.

This figure illustrates the electrical characteristics for the photovoltaic cell 140 in the dark and under illumination. Under illumination, this cell can produce a maximum voltage V_{OC} called the open-circuit voltage and a maximum current density J_{SC} called the short-circuit current density. To generate power, the device is connected to a load with a finite resistance. The value of this resistance is chosen to optimize the product of the voltage and the current density. Maximum power is produced at the voltage Vₘ and current Jₘ shown in FIG. 4B. The power conversion efficiency is then defined by,

$$η = \frac{{V}_{m} {J}_{m}}{{P}_{opt}} \qquad ( 1 )$$

where Pₒₚₜ is defined as the optical power density of the light incident on the photovoltaic cell 140. Since the maximum attainable value for the product of the current and the voltage in the photovoltaic regime depends on the shape of the electrical characteristic of the device, power conversion efficiency is more conveniently defined as

$$η = FF \frac{{V}_{OC} {J}_{SC}}{{P}_{opt}} , \qquad ( 2 )$$

where FF, the fill factor, is defined by

$$FF \frac{{V}_{m} {J}_{m}}{{P}_{opt}} . \qquad ( 3 )$$

The value of these constants can be determined using the current voltage relationship shown in FIG. 4B and the circuit diagram 400.

Analyzing the circuit diagram 400 can indicate how the shunt resistance R_{P} and the series resistance R_{S} impact power conversion efficiency. More specifically, the circuit diagram 400 leads to the following electrical characteristic:

$$J = \frac{1}{1 + {R}_{S} \text{/} {R}_{P}} [ {J}_{S} \{ exp ( \frac{V - {JR}_{S} A}{{nk}_{B} T \text{/} e} ) - 1 \} - ( {J}_{ph} - \frac{V}{{R}_{P} A} ) ] , \qquad ( 4 )$$

where where κ_{B} is the Boltzmann constant, T the temperature in Kelvin, and e the electronic charge. The highest fill factor FF is obtained in the ideal case where series resistance R_{S}=0 and the shunt resistance R_{P}→∞. For non ideal devices, like the photovoltaic cell 140, values of series resistance R_{S} and inverse of the shunt resistance, 1/R_{P}, are kept sufficiently small to maintain a high fill factor FF.

Because the power conversion efficiency η is proportional to fill factor FF as mentioned above, maintaining a high fill factor FF means that the photovoltaic cell 140 has greater power conversion efficiency. In non-ideal devices like this photovoltaic cell, finite values for the series resistance R_{S} and the inverse of the shunt resistance, 1/R_{P} will further reduce the fill factor FF. Hence, these resistances are important parameters for the designing efficient photovoltaic cells, like the photovoltaic cell 140. As a result, the materials that form this photovoltaic cell have morphologies and carrier transport properties that lead preferably to R_{S}=0 and R_{P}→∞.

Physics of the Photovoltaic Cell

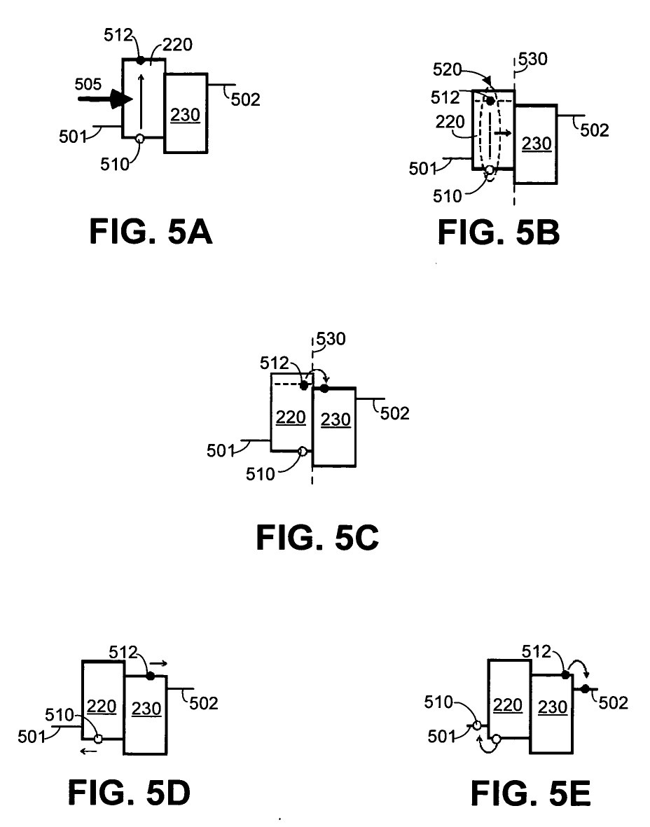

To convert light energy to electrical energy, five physical processes of creation of excitons via absorption of light energy, diffusion of excitons, dissociation of excitons into free carriers, carrier transport, and carrier collection occur within the photovoltaic cell 140. These processes are clearly illustrated in the sequential block diagrams shown in FIG. 5A through FIG. 5E. Moreover, only the portion of the photovoltaic cell 140 that includes the hole transport layer 220 and the electron transport layer 230 is shown. Electrodes 210 and 215 are represented by levels 501 and 502, respectively. Levels 501 and 502 represent the workfunctions of the materials that form the electrodes.

Turning now to FIG. 5A, this block diagram illustrates how light 505 is absorbed by the hole transport layer 220. Light energy can be formed of discrete quanta of light, or photons 505. This photon enters the hole-transport layer 220. Within the hole-transport layer 220 there are numerous electrons in the ground state, for example the electron 512. As the photon 505 is absorbed, the electron 512 in the ground state acquires enough energy to get to an excited state while creating a void of negatively charged particle, which is in turn regarded as a net positively charged particle, or a hole, e.g. the hole 510. This electron and hole pair is bound by an electrostatic force and are thus considered as single entities called excitons.

Turning now to FIG. 5B, an example of the resulting excitons, or the exciton 520 includes the hole 510 and the electron 512. The maximum exciton binding energy Ε_{B} for the hole 510 and the electron 512 is given by

$${E}_{B} = - \frac{{m}^{*} {ⅇ}^{4}}{{( 4 {πɛ}_{0} )}^{2} 2 {ℏ}^{2} {ɛ}^{2}} , \qquad ( 5 )$$

where m* is the effective mass of the electron, ε₀ is the free-space permittivity, ℏ=b/2π where b is Planck's constant, and ε is the dielectric constant of the material in which excitons are formed.

In inorganic semiconductors, like silicon or gallium arsenide, the exciton binding energy is small (e.g., less than 26 meV corresponding to the thermal energy κ_{B}T at room temperature) and the excitons are not stable at room temperature. Therefore, these excitons break up into uncorrelated electrons and holes. In contrast, organic materials, like pentacene and C₆₀, have excitons with much larger exciton binding energies that are significantly higher than the thermal energy at room temperature (Ε_{B}>10 κ_{B}T). As a result, the light absorption does not give rise directly to the creation of charged particles, uncorrelated electrons and holes, but rather to excitons, which are neutral particles because of the association between the hole and the electron. These excitons can move by a diffusion process within hole transport layer 220 as shown in FIG. 5B. Although not shown, excitons created in electron transport layer 230 undergo the same diffusion process.

This difference between organic and inorganic materials can be understood by considering the difference in dielectric constant between these two classes of materials. Silicon has a dielectric constant of 11.8 while most organic materials have dielectric constants on the order of 3. As illustrated above in the binding energy equation, the exciton binding energy scales like 1/ε² and is therefore strongly dependent on the dielectric constant of the material. Before excitons can produce electrical current, they must dissociate into uncorrelated electron-hole pairs. This process can be implemented efficiently at interfaces, or heterojunctions, formed by two different organic materials with different molecular orbital energies. Example of such heterojunctions is shown as 530.

Turning now to FIG. 5C, this block diagram illustrates how an exciton dissociates at the interface 530 between the hole transport layer 220 and the electron transport layer 230. If the energy mismatch between the HOMO and/or LUMO energies in these two layers is larger than, or on the order of the exciton binding energy, the heterojunction at the interface of the electron transport layer 230 and the hole transport layer 220 will dissociate the excitons efficiently into free electrons and holes through electron-transfer reactions. At this interface, the dissociated excitons will lead to electrons located on the right-hand side of the interface in the electron-transport layer 230 and holes on the left-hand side of the interface in the hole-transport layer 220. This is shown more clearly in FIG. 5D. After dissociation, the charge carriers are transported, as indicated by arrows, towards electrodes within these layers by either diffusion or drift. Then these carriers are collected at the electrodes, as can be clearly seen in FIG. 5E.

Of the five physical processes, diffusion of excitons to heterojunctions and subsequent dissociation can have the greatest impact on the power conversion efficiency for the photovoltaic cell 140. It is because excitons created optically by absorption of the light in hole transport layer 220, or electron transport layer 230, or in both layers, can efficiently contribute to the cell photocurrent only if they reach heterojunction 530 where they can dissociate efficiently.

Diffusion process for excitons can be characterized by an exciton diffusion length L, or a characteristic distance over which excitons can travel before they recombine. In other words, only excitons created within a distance L from the nearest heterojunction will efficiently contribute to the photocurrent. Therefore, the thicknesses of transport layers 220 and 230 should not be significantly larger than the respective exciton diffusion lengths corresponding to each layer. If L is too small, and therefore transport layers 220 and 230 cannot be made thick, they will absorb only a small portion of the incoming light, which translate into only a small photocurrent. For instance, a commonly used hole-transport material such as Cu-phthalocyanines (CuPc) has reportedly an exciton diffusion length of less than 10 nm. For a peak extinction coefficient κ=0.74 at a wavelength of λ=620 nm, a corresponding layer will exhibit an absorption coefficient α=4πκ/λ of 0.015 nm⁻¹. The single pass absorption is given by Beer's law:
Abs=(1−exp(−αd)) (6)
where α is the absorption coefficient and d is the sample thickness. For a single pass thickness, a 10 nm thick film can yield absorption of only 14 percent. This illustrates that the small exciton diffusion length can be a severe limitation to the development of efficient photovoltaic cells.

To more fully appreciate the role of the exciton diffusion length, it is helpful to explore the mathematics underlying the transport of excitons. The transport of excitons can be described by the continuity equation:

$$\begin{matrix}\frac{\partial p}{\partial t} = - ∇ \cdot {J}_{EXC} + G - \frac{p}{τ} \\ = D \frac{{\partial }^{2} p}{\partial {z}^{2}} + G - \frac{p}{τ} ,\end{matrix} \qquad ( 7 )$$

where p(zt) is the density of excitons in the material, D is the exciton diffusion coefficient, τ is the exciton lifetime, and G(zt) is the exciton generation rate. This rate is defined by,

$$G = \frac{α I ( z , t )}{hc \text{/} λ} , \qquad ( 8 )$$

where I(zt) is the light intensity in the film. This distribution can be approximated to
I(zt)=I₀(t)exp(−αz). (9)

Occasionally, light may not get absorbed during a first pass, but may get absorbed during a second pass through the transport layers. Light that did not get absorbed during a first single pass gets reflected by the back electrode and makes a second pass through the photovoltaic cell 140. For this situation, I(zt) can be approximated to
I(zt)=I₀exp(−αz)[1+Rexp(2α(z−d))] (10)
in which R is the reflection coefficient of the back electrode, or electrode 215.

Optical interference effects that can occur in the thin-film photovoltaic cell 140 have been neglected in Eqs. 9 and 10. In the general description of the light distribution in the film the multiple reflections and interference among such fields that can occur at the various interfaces in the device has to be considered. These effects can lead to more advantageous light distributions where the light is concentrated in one of the transport layers. For the sake of simplicity, only I(zt) following Beer's law of single-pass (Eq. 9) and double-pass cases (Eq. 10) are considered. At steady-state (∂p/∂t=0), the continuity equation can be rewritten as:

$$D \frac{{\partial }^{2} p}{\partial {z}^{2}} + G - \frac{D \cdot p}{{L}^{2}} = 0 , \qquad ( 11 )$$

where L is defined as L=(Dτ)^{1/2}.

As previously mentioned, only excitons that dissociate at the interface between the hole-transport, or donor, layer 220 and the electron-transport, or acceptor, layer 230 can contribute to the photocurrent produced by the photovoltaic cell 140. Excitons that dissociate at the donor/acceptor heterojunction contribute to the photocurrent J_{pb} that is given by:
Jₚₕ=Σᵢeη_{cs}η_{cc}|Dᵢpᵢ′|, (i=D or A), (12)
where the subscript i refers to either the donor (D) layer 220 or acceptor (A) layer 230, pᵢ′ is the spatial derivative of pᵢ(z) at the donor/acceptor heterojunction 530, and η_{cs} and η_{cc} are quantum efficiencies associated with exciton dissociation and charge collection, respectively. Since the current is proportional to the spatial derivative of the exciton density at the interface, the knowledge of the steady-state exciton distribution within the photovoltaic cell 140 does allow for the calculation of the photocurrent. The steady-state spatial distribution of excitons is obtained by solving the steady-state continuity equation. The general solution will depend on boundary conditions that are characterized by surface recombination velocities:

$$D \frac{\partial p}{\partial z} {\vert}_{z = {z}_{0}} = S p ( {z}_{0} ) , \qquad ( 13 )$$

where S is the surface recombination velocity at an interface. The situation where S=∞ corresponds to the case where all the excitons are completely quenched or dissociated at the interface leading to the boundary condition equivalent to p(z₀)=0. This is generally the case at the donor/acceptor heterojunction 530 if the mismatch in orbital energies is favorable for exciton dissociation. On the other hand, S=0 corresponds to the case where the excitons are preserved [∂p/∂z=0 at z=z₀.]. In non-ideal situations, S is expected to deviate from these extremes.

The level of complexity of the solutions of the steady-state continuity equation with these boundary conditions depends mainly on the spatial dependence of the exciton generation rate G(z) that is directly proportional to the distribution of absorbed light in the photovoltaic device 140.

To illustrate the importance of the interplay between absorption coefficient α layer thickness d and the exciton diffusion length L on the external quantum efficiency, or the ratio of the number of generated photocarriers to that of incident monochromatic photons of organic photovoltaic cells, the simple case study where the optical intensity drops exponentially according to Beer's law along the propagation direction (z-direction) is considered first. In this analysis, the surface recombination velocity at the z=0 and z=d interfaces are chosen S=0 and S=∞, respectively. z is a distance measured from the location of interface between the anode 210 (or 214, if applicable) and the carrier transport layer 220. z=d corresponds to the location of the heterojunction 530 between the carrier transport layers 220 and 230. For simplicity, only photocarriers created within the layer 220 are considered. When the thickness of the layer 230 is small such that its optical absorption can be ignored, all the photons that are not absorbed in the first pass can be reflected by the electrode 215 and will be absorbed during a second pass in layer 220. The case with a double pass is also considered to illustrate the importance of the interplay between absorption coefficient α layer thickness d and the exciton diffusion length L on the external quantum efficiency.

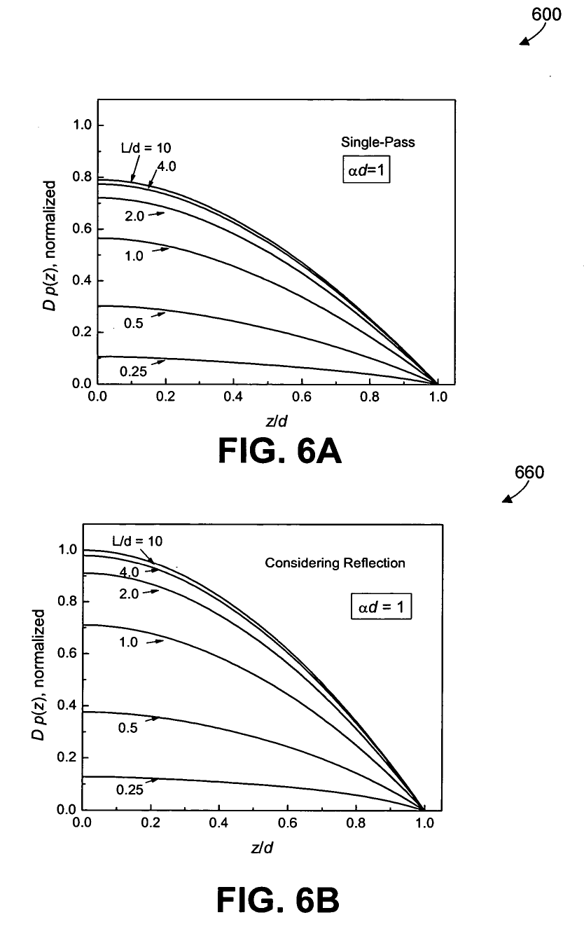

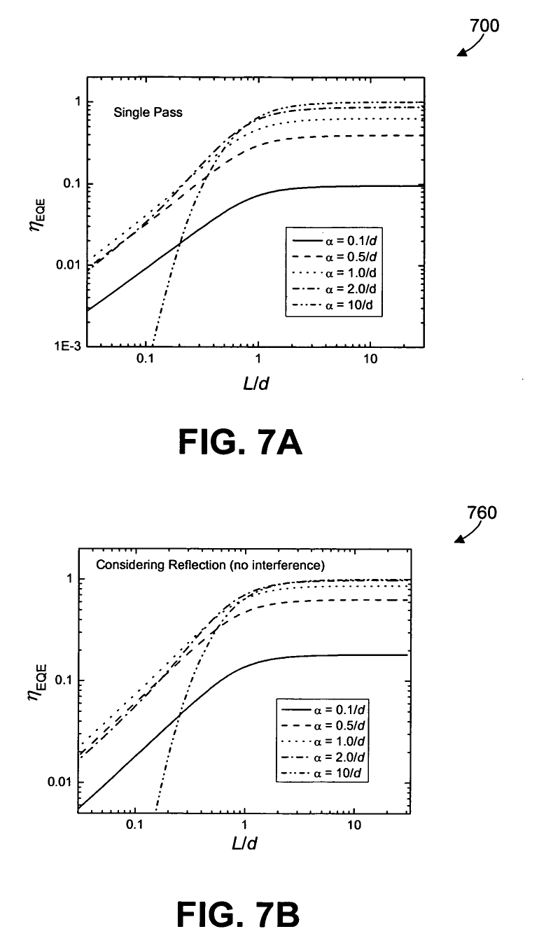

Turning now to FIG. 6A, graph 600 shows the effect of limited diffusion length L on the steady-state exciton distribution p(z). In this analysis, the thickness d of the layer 220 was fixed to the corresponding skin depth defined by d₀=1/α. The skin depth is the distance over which the intensity is significantly reduced, or more specifically, falls to the 1/e=0.368 of the value at z=0. In this case, the light absorption becomes 63.2% for a single pass and 86.5% for a double pass, assuming R=1, using Eqs. 9 and 10, respectively. Note that the thickness of the layer 220 is preferably comparable to or larger than the skin depth to harvest as many photons as possible. Referring to graphs 600 and 660 in FIG. 6A and FIG. 6B, respectively, decreasing values of the diffusion length L translates into an overall decrease of the exciton density in the film that in turn translates into lower values for the photocurrent. It becomes apparent from this analysis that materials with exciton diffusion lengths that are significantly lower than the thickness of the film will have limited performance because a significant portion of excitons recombines before they reach the heterojunction 530. Reduction of the device thickness d may circumvent the problem associated with a small L/d ratio, but then a low absorption can limit the efficient photocurrent generation. The effect of the limited absorption is clearly illustrated in FIG. 7A and FIG. 7B in graphs 700 and 760, showing both single-pass and double-pass cases, respectively.

Recalling that CuPc films have an absorption coefficient α of 0.015 nm⁻¹, the thickness corresponding to its skin depth would be 1/0.015 nm=67 nm. In this case L/d ratio is 0.15 as L for CuPc is ˜10 nm. As shown in graphs 600 and 660 in FIG. 6A and FIG. 6B, respectively, such conditions would lead to very low steady-state exciton densities. Therefore, layer thicknesses of CuPc layers that have been employed in organic photovoltaic cells generally do not exceed 10-20 nm. In this case, the excitons that are produced in the film can diffuse efficiently to the heterojunction 530. However, with an absorption coefficient of α=0.015 nm⁻¹ at a wavelength of λ=620 nm a 10 nm-thick film absorbs only 14% of the incoming light for a single pass. Such a low absorption limits the power conversion efficiency of a photovoltaic cell, as previously shown in graphs 700 and 760 FIG. 7A and FIG. 7B. This illustrates the interplay between absorption and exciton diffusion length. This analysis shows that hole and electron transport materials used in photovoltaic cells should preferably have absorption coefficients α and exciton diffusion lengths L that maximize the product α L, with values for α L>0.2-0.3, or preferably α L>˜1.

Fabrication, Characterization and Operation of Illustrative Photovoltaic Cell

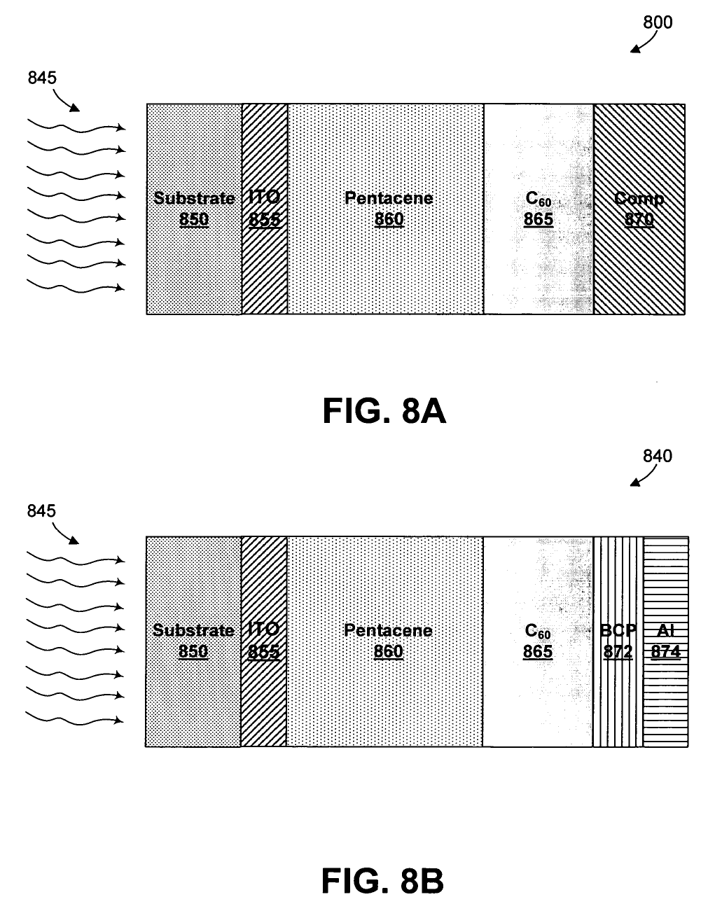

Turning now to FIG. 8A, this figure is a cross-sectional view of an illustrative photovoltaic cell 800 illustrating materials used to fabricate the photovoltaic cell. The photovoltaic cell 800 is one of the many possible implementations of the photovoltaic cell 140. Light energy 845, in the form of photons (discrete quanta of light), can enter this cell through a transparent substrate 850. The substrate can be composed of glass, plastic or transparent inorganic oxides or any combination of those. The anode 855 in the photovoltaic cell 800 is composed of indium tin oxide. The hole-transport layer 860 includes pentacene, while the electron transport layer 865 includes C₆₀. The composite cathode 870 includes a buffer layer and a metal. FIG. 8B shows an example of bathocuproine (BCP) as a buffer layer 872 and Aluminum as a metal 874 used in the photovoltaic cell.

For the photovoltaic cell 840, there can be specific methods associated with the fabrication of each layer. For example, the organic materials in the hole-transport layer 860 and the electron-transport layer 865 can be purified by thermal gradient sublimation under a vacuum of 10⁻⁶ Torr before use. Subsequently, these layers and the cathode 870 can be sequentially deposited through shadow masks onto the pre-cleaned anode 855, or ITO substrate. More specifically, the layers can be deposited on the transparent electrode layer using physical vapor deposition (PVD) or some other suitable deposition method. The ITO can be etched so that several photovoltaic cells, such as the photovoltaic cell 840, with an area of approximately 0.1 cm² or preferably larger than 1 cm² may be formed. All the photovoltaic properties can be measured in an N₂-filled glove box without exposure of the devices to ambient air. A broadband light, such as a 175 Watt Xenon lamp, can be used as broadband light source to simulate the solar spectrum for producing the light energy 845. This light energy can be measured with a calibrated Silicon photodiode.

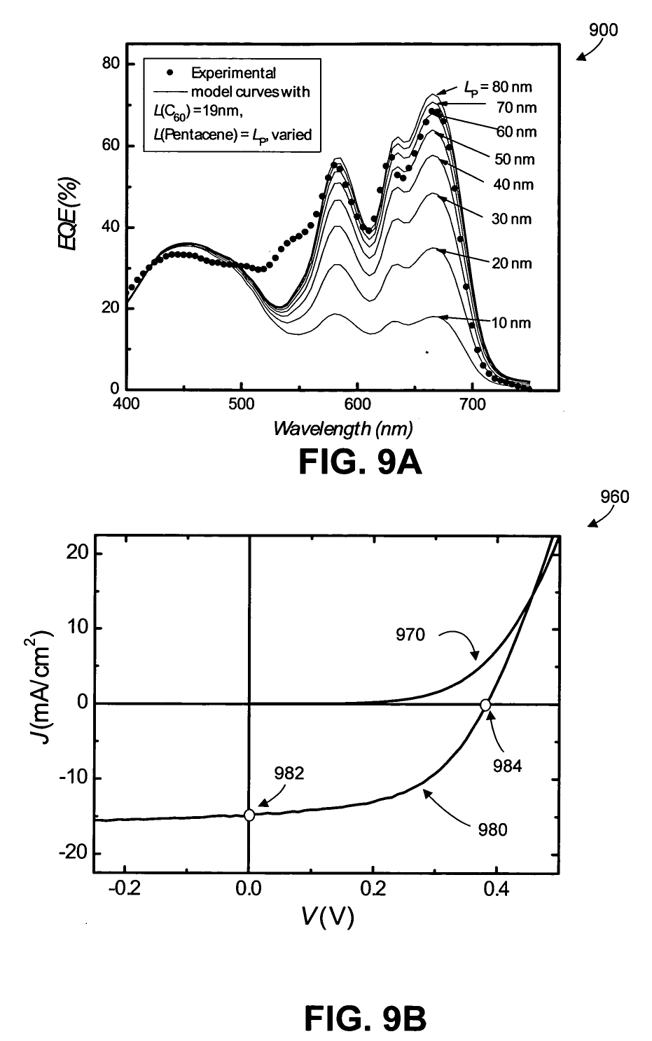

Active layers, or carrier transport layers, should possess as large exciton diffusion length as possible in order to achieve high external quantum efficiency. The optimum thickness of donor layer 860 or acceptor layer 865 is usually on the order of its diffusion length, but it can vary depending on the optical field distribution. Interference effects can have a significant influence on the photocurrent generation, and, therefore, the thicknesses of layers are optimized to allow large absorption in an active layer of concern, and thereby a high external quantum efficiency. Turning now to FIG. 9A, graph 900 shows the experimental external quantum efficiency measured as function of the incident wavelength for the photovoltaic cell 840 in which pentacene layer 860 has a thickness of 45 nm, C₆₀ layer 865 a thickness of 50 nm, and BCP layer 872 a thickness of 6 nm. In addition, graph 900 shows the modeling of the external quantum efficiency as a function of the incident wavelength for increasing values of the exciton diffusion length L in pentacene. The calculation shows a good agreement with the experimental value for an exciton diffusion length in pentacene of 60 nm. Since pentacene has a maximum extinction coefficient of κ=0.43 at a wavelength of λ=670 nm its absorption coefficient α=4πκ/λ is 0.008 nm⁻¹. With an exciton diffusion length of L=60 nm, the product α L is 0.48. The current voltage characteristic of device 840 with a pentacene layer 860 of 45 nm, a C₆₀ layer 865 of 50 nm, and a BCP layer 872 of 6 nm is shown in graph 960 of FIG. 9B. Curve 970 shows the characteristic in the dark, and curve 980 the characteristic under illumination of a solar simulator with an intensity of 86 mW/cm². As shown in graph 960, the open circuit voltage 984 is 383 mV and the short circuit current 982 is 14.7 mA/cm². The fill factor for curve 980 is 0.52. Based on Eq. 2 these values lead to a power conversion efficiency of 3.4% and illustrates the high efficiency of cell 840.

The table shown below summarizes the effect on photovoltaic characteristics of the thickness d of pentacene layer 860 of devices fabricated at the same time with a geometry 840 shown in FIG. 8B where the thickness of electron transport layer 865 was kept constant at 30 nm and BCP layer 872 was kept constant at 8 nm. The increase in the short-circuit current density upon increase in d the thickness of pentacene layer 860 up to 100 nm clearly demonstrates the beneficial impacts of large exciton diffusion length of pentacene layer on photocurrent generation.

TABLE 1

| Pentacene layer | | | | Efficiency |
|---|---|---|---|---|
| thickness (nm) | V_{OC} (mV) | J_{SC} (mA/cm²) | FF | (%) |
| 20 | 232 ± 5 | 7.8 ± 0.7 | 0.49 ± 0.006 | 0.94 ± 0.09 |
| 50 | 291 ± 3 | 11.3 ± 0.2 | 0.48 ± 0.02 | 1.70 ± 0.06 |
| 70 | 266 ± 5 | 11.4 ± 0.4 | 0.46 ± 0.008 | 1.50 ± 0.01 |
| 100 | 318 ± 1 | 12.2 ± 0.2 | 0.48 ± 0.007 | 2.00 ± 0.05 |

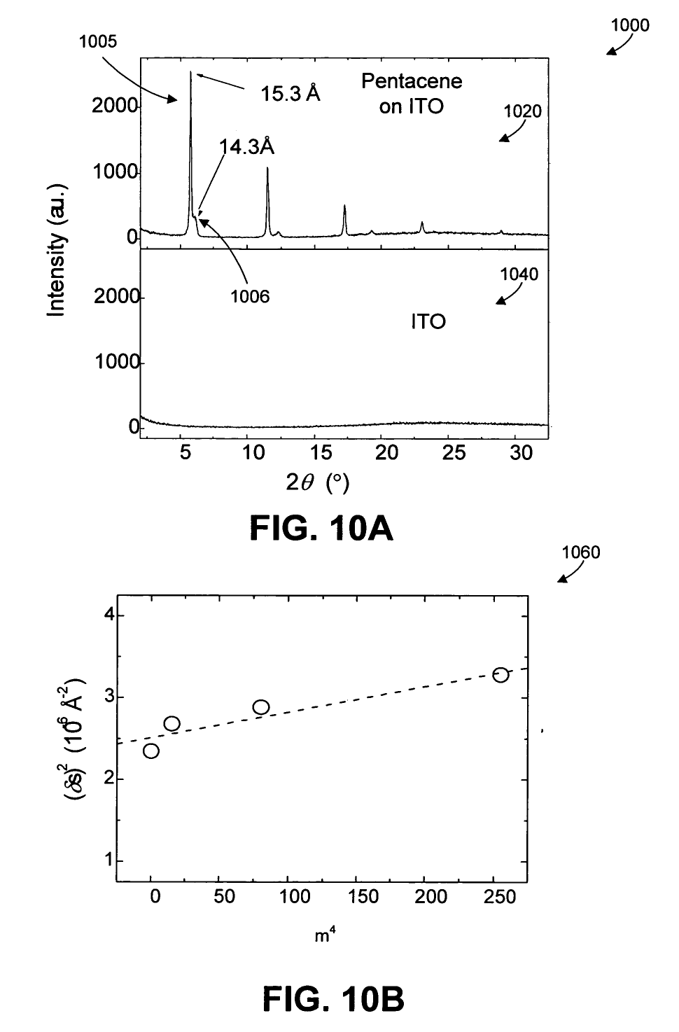

The origin of the large exciton diffusion length in pentacene can be related to the norphology of the pentacene film. Turning now to FIG. 10A, graph 1000 shows the results of X-ray diffraction (XRD) carried-out on the same samples. XRD technique is generally used to obtain crystallographic information on specimens under test. More specifically, when used with thin-film specimens, this XRD measurement gives the information on inter-planar distances between adjacent planes that are parallel to a substrate, or d_{z}. Molecular arrangement with a highly crystalline order result in narrow peaks while amorphous arrangement result in no peaks or at most very broad features with a relatively low signal intensity. The location of such peaks are related to d_{z} by the Bragg diffraction equation, m λ=2 d_{z} sin θ, in which m is the diffraction order (m=1, 2, 3, . . . ), λ the wavelength of X-ray source, and the diffraction angle θ. A series of major peaks observed in window 1020 of graph 1000 the XRD results corresponds to d_{z} of 15.3 Å and is consistent with that of so-called “thin-film” crystalline phase of pentacene thin films (typically around 100 nm or less) deposited by physical vapor deposition. A series of small peaks 1006 next to the major peak 1005 is associated with the crystalline morphology with d_{z}=14.3 Å, which has been identified as “bulk phase” because this phase is typically found in pentacene bulk single crystals. Bulk phase is known to set in only after a certain critical thickness. The X-ray data shown in window 1030 of graph 1000 taken on a bare ITO sample does not show diffraction peaks, indicating that peaks such as 1005 in window 1020 are caused by the pentacene film.

While the domain size in the transverse direction is mostly of concern in the case of devices like field-effect transistors where carriers are transported along the direction parallel to the surface, the vertical dimension of each domain or crystallite is particularly of concern for photovoltaic cells, in which carriers and excitons are flowing in a direction perpendicular to a substrate in most cases. The mean dimension of crystallites in a direction perpendicular to the substrate, or <l_{z}>, including the additional broadening effect due to fluctuations in lattice translation vectors, can be estimated from the following equation:

$$δ {s}_{m} ≡ \frac{2 cos {θ}_{m} {δθ}_{m}}{λ} \approx \sqrt{\frac{1}{{〈 {l}_{z} 〉}^{2}} + \frac{{π}^{4} {g}^{4 }}{{〈 {d}_{z} 〉}^{2}} {m}^{4}} \qquad ( 14 )$$

in which θₘ and δθₘ are the diffraction angle and full-width half maximum (FWHM) in radian for the m-th order peak, <d_{z}> the average value of d_{z}, and g the mean fluctuation of the lattice vector perpendicular to planes of concern, that is, (Δd_{z})/<d_{z}>. Using this relation, <l_{z}>≈63 nm with g of approximately 1% is estimated (see graph 1060 in FIG. 10B). The low g-value and large <l_{z}> that is comparable to the layer thickness and also to the estimated exciton diffusion length of pentacene film indicate the high crystallinity of the pentacene film grown on ITO. It is noted that this estimation provides a lower limit because it does not take into account the instrument-related broadening effect and that <l_{z}> can actually be estimated to a larger value if that is also included. The large crystallites in a direction normal to the substrate should be regarded as important because the actual exciton diffusion could otherwise be interrupted or hindered, regardless of intrinsic diffusion length, at the crystallite boundary. It is also noted that the terraced pyramidal structure of the pentacene layer may promote the charge transfer reaction at the interface not only by increasing the surface area but also by allowing face-to-face interaction (rather than edge-on) between pentacene and C₆₀ molecules, leading to larger electron cloud overlap and higher electronic coupling.

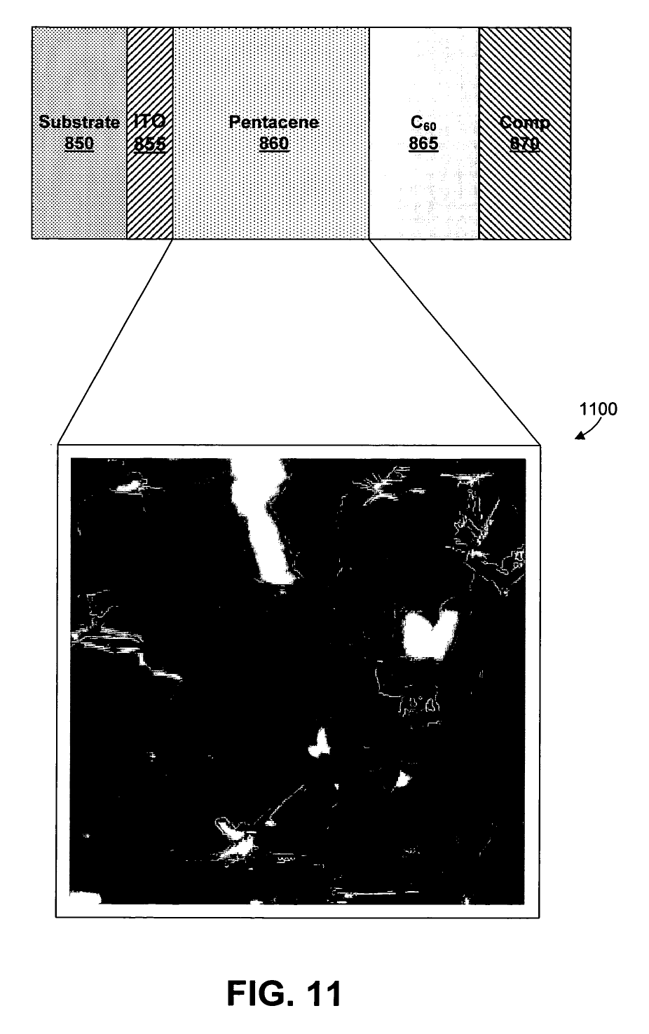

Turning now to FIG. 11, picture 1100 this figure shows an atomic force microscopy (AFM) image of pentacene thin films (˜100 nm thick) prepared on an ITO substrate using the deposition condition employed for photovoltaic device fabrication. The image obtained over 3 μm×3 μm shows polycrystalline domains with a size ranging from several hundred nanometers to slightly less than 1 μm. A close-up view of the film on ITO shown in picture 1100 reveals terrace-like features, indicative of layer-by-layer growth. The steps in the terrace-like features are found to be roughly equal to 1-2 times the layer spacing typically found in pentacene thin films, which is approximately ˜15 Å. The resultant pyramidal morphology yields average roughness of 13% of the total film thickness, over the measured area. Since these textured surfaces still maintain a high degree of ordering, they should be differentiated from simply rough and essentially disordered surfaces that may be found in other materials or those which may result from flash deposition or from high substrate roughness.

While various embodiments of the invention have been described, it can be apparent to those of ordinary skill in the art that many more embodiments and implementations are possible that are within the scope of this invention. All such modifications are intended to be included within the scope of this disclosure and protected by the following claims.

What is claimed is:

1. A photovoltaic cell comprising:
a polycrystalline carrier transport layer;
a second carrier transport layer positioned over the polycrystalline carrier transport layer and operative for dissociating excitons at a junction between the polycrystalline carrier transport layer and the second carrier transport layer; and
first and second electrodes respectively coupled to the polycrystalline carrier transport layer and the second carrier transport layer, wherein the electrodes are operative for collecting the charge carriers.

2. The photovoltaic cell of claim 1, wherein the polycrystalline carrier transport layer is selected from the group of organic materials consisting of tetracene, pentacene, hexacene, and functionalized pentacene.

3. The photovoltaic cell of claim 1, wherein the first electrode is selected from the group of transparent compositions consisting of indium tin oxide, fluorine-doped tin oxide, zinc oxide, and 3,4-polyethylenedioxythiophene polystrenesulfonate.

4. The photovoltaic cell of claim 1, wherein the second electrode is a composite electrode.

5. The photovoltaic cell of claim 1, wherein the second electrode is selected from the group of metals consisting of aluminum, gold, silver, copper, calcium, magnesium, and metal mixtures.

6. The photovoltaic cell of claim 1, wherein the polycrystalline carrier transport layer has an absorption coefficient and an exciton diffusion length, and the product of the absorption coefficient and the exciton diffusion length is greater than approximately 0.2.

7. The photovoltaic cell of claim 6, wherein product of the absorption coefficient and the exciton diffusion length is greater than approximately 1.

8. The photovoltaic cell of claim 1, further comprising a substrate under the first electrode, wherein the substrate is selected from the group consisting of plastic and glass.

9. A photovoltaic cell, comprising:
a polycrystalline hole transport layer having an exciton diffusion length and an absorption coefficient, wherein the product of the exciton diffusion length and the absorption coefficient is greater than approximately 0.2;
an electron transport layer over the polycrystalline hole transport layer and operative for dissociating excitons at a junction between the polycrystalline hole transport layer and the electron transport layer; and
first and second electrodes respectively coupled to the polycrystalline hole transport layer and the electron transport layer, wherein the electrodes are operative for collecting the charge carriers.

10. The photovoltaic cell of claim 9, wherein the product of the absorption coefficient and the exciton diffusion length is greater than approximately 1.0.

11. The photovoltaic cell of claim 9, wherein the electron transport layer is a polycrystalline electron transport layer having an exciton diffusion length and an absorption coefficient, and the product of the absorption coefficient and the exciton diffusion length for the polycrystalline electron transport layer is greater than approximately 0.2.

12. The photovoltaic cell of claim 10, wherein the polycrystalline hole transport layer is selected from the group organic materials consisting of tetracene, pentacene, hexacene, and functionalized pentacene.

13. The photovoltaic cell of claim 8, wherein the first electrode is selected from the group of transparent compositions consisting of indium tin oxide, fluorine-doped tin oxide, zinc oxide, and 3,4-polyethylenedioxythiophene polystrenesulfonate.

14. A method for fabricating a photovoltaic cell, comprising the steps of:
forming a first electrode on a substrate;
depositing a first organic material on the substrate, wherein the organic material forms a first polycrystalline carrier transport layer having an absorption coefficient and an exciton diffusion length, wherein the product of the absorption coefficient and the exciton diffusion length is greater than approximately 0.2;
depositing a second material on the first organic material, wherein the second material forms a second carrier transport layer; and
depositing a second electrode on the second polycrystalline material.

15. The method of claim 14, wherein the step of depositing a second material further comprises depositing a second organic material that forms a second polycrystalline material layer.

16. The method of claim 14, the step of depositing a second organic material forms a second polycrystalline material layer having an absorption coefficient and an exciton diffusion length, where the product of the absorption coefficient and the exciton diffusion length for the second polycrystalline transport layer is greater than approximately 0.2.

17. The method of claim 14, wherein the step of depositing a first organic material comprises depositing an organic material selected from the group consisting of tetracene, pentacene, hexacene and functionalized pentacene.

18. The method of claim 14, wherein the step of depositing a second material comprises depositing a composition selected from the group consisting of carbon-60 and copper hexadecaflurophthalocyanies.

19. The method of claim 14, wherein the step of depositing a first electrode comprises deposing a composition selected from the group of transparent compositions consisting of indium tin oxide, fluorine-doped tin oxide, zinc oxide, and 3,4-polyethylenedioxythiophene:polystrenesulfonate.

20. The method of claim 14, wherein the step of depositing a second electrode comprises depositing a composition selected from the group consisting of second electrode is selected from the group of metals consisting of aluminum, gold, silver, copper, calcium, magnesium, and metal mixtures.
